(19) United States
(12) Patent Application Publication
(10) Pub. No.: US 2016/0146920 A1
(43) Pub. Date: May 26, 2016

(54) RF PARAMETER CALIBRATION METHOD

(71) Applicant: SIGURD MICROELECTRONICS CORP., Shin-Chu (TW)

(72) Inventors: CHIEN-HUNG LIN, SHIN-CHU (TW); YI-CHENG TSAI, SHIN-CHU (TW); CHING-CHENG TIEN, SHIN-CHU (TW); CHI-CHUNG LIU, SHIN-CHU (TW)

(21) Appl. No.: 14/548,472

(22) Filed: Nov. 20, 2014

(51) Int. Cl. G01R 35/00; G01R 27/06

(52) U.S. Cl. CPC G01R 35/005; G01R 27/06

(57) ABSTRACT

An RF parameter calibration method comprises steps: measuring an open-circuit parameter, a short-circuit parameter and a load parameter of an RF parameter circuit of a tested object; respectively substituting measured values of the open-circuit parameter, the short-circuit parameter and the load parameter into a directivity error equation, a signal source matching error equation, and a reflection path error equation to obtain a directivity error, a signal source matching error, and a reflection path error; substituting the directivity error, the signal source matching error and the reflection path error into an RF parameter equation to work out an actual value of an RF parameter; examining whether the actual value of the RF parameter is smaller than a preset dB value; if yes, undertaking calibration; if no, returning to undertake measurements once again. The present invention can replace the expensive standard calibration kit and achieve more precise parameter calibration.

### BACKGROUND OF THE INVENTION

1. Field of the Invention

The present invention relates to an RF parameter calibration method, particularly to an RF parameter calibration method able to perform more precise parameter calibration.

2. Description of the Related Art

In a high-frequency circuit, it is very hard to define an absolute open-circuit state and an absolute short-circuit state. Further, total current and total voltage is hard to measure in the network. Besides, some active elements, such as transistors and diodes, cannot work steadily in an open-circuit state or a short-circuit state. In a high-frequency circuit, it is easier to measure incident power and reflected power. Therefore, incident power and reflected power are used to define the parameters for the design of a high frequency circuit, i.e. the so-called RF parameters or S (Scattering) parameters.

The ordinary equations for calculating RF parameters are described as follows. Refer to FIG. 1 for a signal flow graph of an ideal network analysis tool. In the ideal tool, it is supposed that S_{11A} can be directly learned from S_{11M}. However, the fact is not so. Therefore, the tool error needs modeling. As shown in FIG. 2, S_{11M} is a function of a directivity error E_{D}, a signal source matching error E_{S}, a reflection path error E_{RT} and S_{11A}. According to the signal flow graph, S_{11M} can be expressed by Equation (1-1):

$${S}_{11 M} = {E}_{D} + \frac{{S}_{11 A} \cdot {E}_{R T}}{1 - {E}_{S} {S}_{11 A}} \qquad ( 1 \text{-} 1 )$$

Via measuring a perfect load of a standard calibration kit and substituting 0<0°=S_{11A} into Equation (1-1), Equation (1-1) is transformed into Equation (1-2):

$${S}_{11 M L} = {E}_{D} + \frac{( 0 ) \cdot {E}_{R T}}{1 - {E}_{S} ( 0 )} \qquad ( 1 \text{-} 2 )$$

Thus, a forward reflection parameter S₁₁ is obtained in measuring an actual load, i.e. S_{11ML}=E_{D}.

Via undertaking measurement in the short-circuit state, Equation (1-3) is obtained:

$${S}_{11 M S} = {E}_{D} + \frac{{S}_{11 AS\_ 85052 D} \cdot {E}_{R T}}{1 - {E}_{S} {S}_{11 AS\_ 85052 D}} \qquad ( 1 \text{-} 3 )$$

wherein S_{11MS} is the S₁₁ measured in the actual short-circuit state and S_{11AS}_{_}_{85052D} is the S₁₁ in the short-circuit state of the standard calibration kit (85052D).

Via undertaking measurement in the open-circuit state, Equation (1-4) is obtained:

$${S}_{11 M O} = {E}_{D} + \frac{{S}_{11 AO\_ 85052 D} \cdot {E}_{R T}}{1 - {E}_{S} {S}_{11 AO\_ 85052 D}} \qquad ( 1 \text{-} 4 )$$

wherein S_{11MO} is the S₁₁ measured in the actual open-circuit state and S_{11AO}_{_}_{85052D} is the S₁₁ in the open-circuit state of the standard calibration kit (85052D).

Next, E_{S} and E_{RT} are obtained via solving Equations (1-3) and (1-4) simultaneously. After E_{S} and E_{RT} are known, S_{11A}_{_}_{Dut}, which is the actual S₁₁ of the tested object, is worked out with Equation (1-5):

$${S}_{11 A\_Dut} = \frac{( {S}_{11 M\_Dut} - {E}_{D} )}{{E}_{R T} + {E}_{S} ( {S}_{11 M\_Dut} - {E}_{D} ) )} \qquad ( 1 \text{-} 5 )$$

The conventional calibration method substitutes the results of measuring the standard calibration kit into the equations, which is likely to output incorrect values. Besides, the standard calibration kit is very expensive, which would increase the cost of the conventional calibration method.

Accordingly, the present invention proposes an RF parameter calibration method to overcome the abovementioned problems.

### SUMMARY OF THE INVENTION

The primary objective of the present invention is to provide an RF parameter calibration method, whose calibration equations cooperate with non-standard measurement values to calibrate the RF parameters and achieve more precise parameter calibration without using the expensive standard calibration kit.

Another objective of the present invention is to provide an RF parameter calibration method featuring simpler computation, more accurate outputs and lower cost than the conventional calibration method using the standard calibration kit.

To achieve the abovementioned objectives, the present invention proposes an RF parameter calibration method, which comprises Step a: measuring the open-circuit parameter, the short-circuit parameter and the load parameter of the RF parameter circuit of a tested object; Step b: respectively substituting the measured values of the open-circuit parameter, the short-circuit parameter and the load parameter into a directivity error equation, a signal source matching error equation, and a reflection path error equation to obtain a directivity error, a signal source matching error, and a reflection path error; Step c: substituting the directivity error, the signal source matching error and the reflection path error into an RF parameter equation to work out an actual value of the RF parameter, wherein the RF parameter equation is expressed as

(S_{11M}−E_{D})*(1−E_{S}−S_{11A})=E_{RT}−S_{11A}

wherein E_{RT} is the reflection path error, E_{D} the directivity error, E_{S} the signal source matching error, S_{11M} a measured value of the RF parameter, and S_{11A} an actual value of the RF parameter; Step d: examining whether the actual value of the RF parameter is smaller than a preset dB value; if yes, undertaking the RF parameter calibration; if no, the process returns to Step a to undertake measurements once again.

Below, the embodiments are described in detail to make easily understood the objectives, technical contents, characteristics and accomplishments of the present invention.

### BRIEF DESCRIPTION OF THE DRAWINGS

FIG. 1 shows a signal flow graph of an ideal network analysis tool in the conventional technology;

FIG. 2 shows an error model of FIG. 1;

FIG. 3 shows a block diagram of a system used by the present invention; and

FIG. 4 shows a flowchart of an RF parameter calibration method according to one embodiment of the present invention.

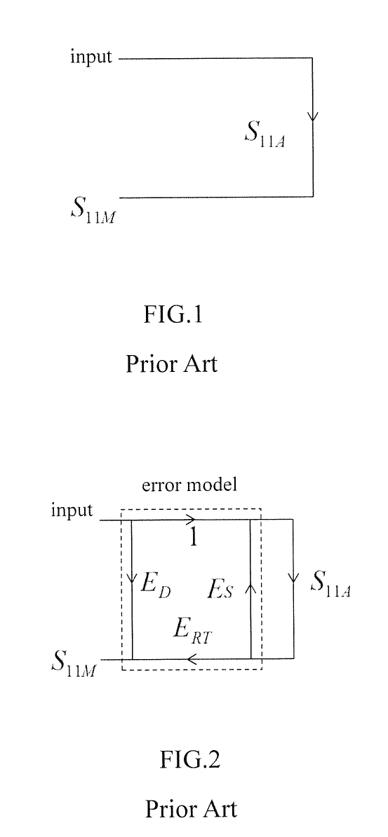

### DETAILED DESCRIPTION OF THE INVENTION

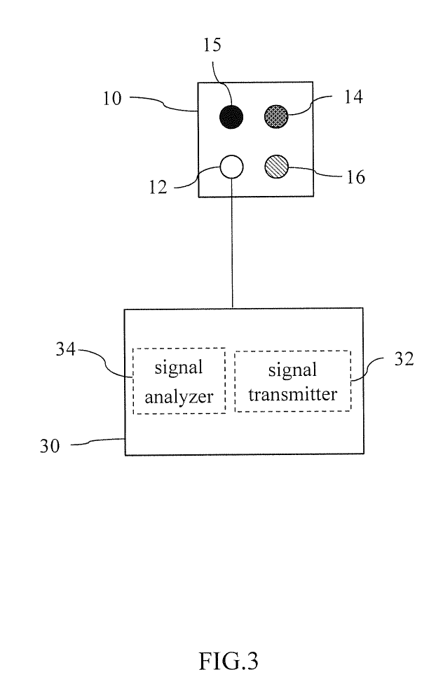

Refer to FIG. 3 a block diagram of a system used to demonstrate one embodiment of the present invention. The system has an electronic switching device 10. The electronic switching device 10 includes a short-circuit measurement terminal 14 for measuring the value of a short-circuit parameter, an open-circuit measurement terminal 15 for measuring the value of an open-circuit parameter, a load measurement terminal 16 for measuring the value of a load parameter, and a signal terminal 12 having a bidirectional transmission function and able to receive and transmit signals. The signal terminal 12 is electrically connected with a device 30. The device 30 includes a signal transmitter 32 and a signal analyzer 34. The device 30 transmits a signal source to the signal terminal 12. The switching device 10 switches one of the short-circuit measurement terminal 14, the open-circuit measurement terminal 15, and the load measurement terminal 16 to output the signal needing measurement through the signal terminal 12 to the device 30. Then, the signal analyzer 34 of the device 30 analyzes the received signal.

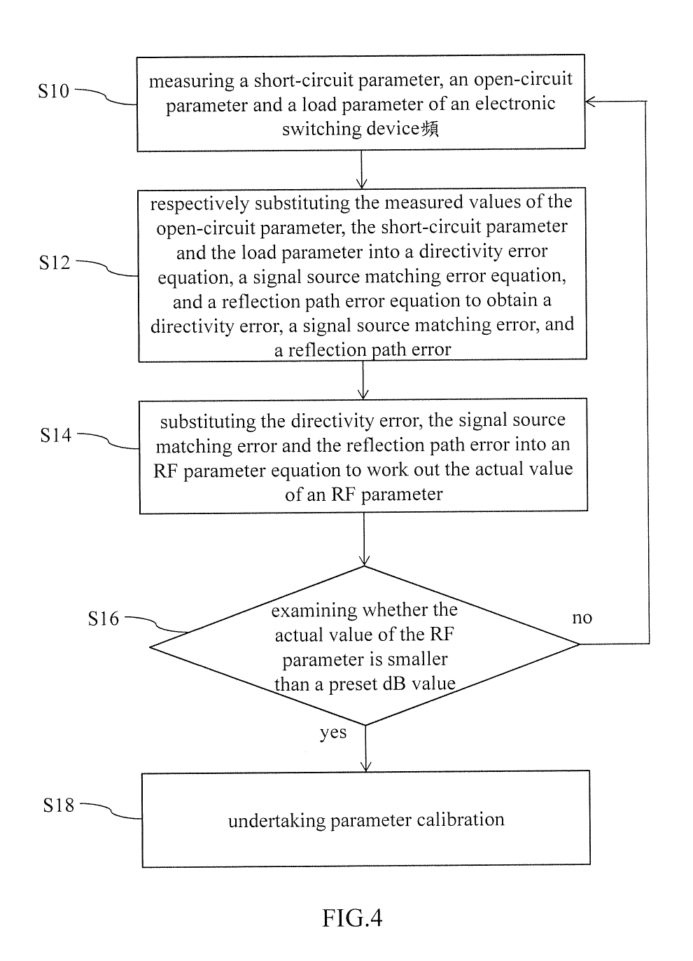

Refer to FIG. 3 again, and refer to FIG. 4 for a flowchart of an RF parameter calibration method according to one embodiment of the present invention. In addition to the abovementioned system measuring the values of the short-circuit parameter, the open-circuit parameter and the load parameter for calculating and calibrating the RF parameter, the method of the embodiment also applies to other signal measurement devices. In the embodiment shown in FIG. 4, the RF parameter calibration method comprises Steps S10-S18. In Step S10, measure the short-circuit measurement terminal 14, the open-circuit measurement terminal 15 and the load measurement terminal 16 of the electronic switching device 10 to obtain the short-circuit parameter, the open-circuit parameter and the load parameter. In one embodiment, the electronic switching device 10 is an RF parameter circuit having a tested object and measuring the short-circuit parameter, the open-circuit parameter and the load parameter of the tested object. The electronic switching device 10 is used to demonstrate the embodiment shown in FIG. 4. In Step S12, respectively substitute the measured values of the open-circuit parameter, the short-circuit parameter and the load parameter into a directivity error equation, a signal source matching error equation, and a reflection path error equation to obtain a directivity error, a signal source matching error, and a reflection path error.

The directivity error equation is expressed by Equation (1):

$${E}_{D} = \frac{\begin{matrix}{S}_{11 A L} * {S}_{11 M L} * {S}_{11 A O} * {S}_{11 M S} - \\ {S}_{11 A L} * {S}_{11 M L} * {S}_{11 M O} * {S}_{11 A S} - \\ {S}_{11 A L} * {S}_{11 A O} * {S}_{11 M O} * {S}_{11 M S} + \\ {S}_{11 M L} * {S}_{11 A O} * {S}_{11 M O} * {S}_{11 A S} + \\ {S}_{11 A L} * {S}_{11 M O} * {S}_{11 A S} * {S}_{11 M S} - \\ {S}_{11 M L} * {S}_{11 A O} * {S}_{11 A S} * {S}_{11 M S}\end{matrix}}{\begin{matrix}{S}_{11 A L} * {S}_{11 M L} * {S}_{11 A O} - \\ {S}_{11 A L} * {S}_{11 A O} * {S}_{11 M O} - \\ {S}_{11 A L} * {S}_{11 M L} * {S}_{11 A S} + \\ {S}_{11 A O} * {S}_{11 M O} * {S}_{11 A S} + \\ {S}_{11 A L} * {S}_{11 A S} * {S}_{11 M S} - \\ {S}_{11 A O} * {S}_{11 A S} * {S}_{11 M S}\end{matrix}} \qquad ( 1 )$$

wherein E_{D} is the directivity error, S_{11AS} the actual value of the short-circuit parameter, S_{11AO} the actual value of the open-circuit parameter, S_{11AL} the actual value of the load parameter, S_{11MS} the measured value of the short-circuit parameter, S_{11MO} the measured value of the open-circuit parameter, and S_{11ML} the measured value of the load parameter.

The signal source matching error equation is expressed by Equation (2):

$${E}_{S} = \frac{\begin{matrix}{S}_{11 A L} * {S}_{11 M O} - {S}_{11 M L} * {S}_{11 A O} - \\ {S}_{11 A L} * {S}_{11 M S} + {S}_{11 M L} * {S}_{11 A S} + \\ {S}_{11 A O} * {S}_{11 M S} - {S}_{11 M O} * {S}_{11 A S}\end{matrix}}{\begin{matrix}{S}_{11 A L} * {S}_{11 M L} * {S}_{11 A O} - \\ {S}_{11 A L} * {S}_{11 A O} * {S}_{11 M O} - \\ {S}_{11 A L} * {S}_{11 M L} * {S}_{11 A S} + \\ {S}_{11 A O} * {S}_{11 M O} * {S}_{11 A S} + \\ {S}_{11 A L} * {S}_{11 A S} * {S}_{11 M S} - \\ {S}_{11 A O} * {S}_{11 A S} * {S}_{11 M S}\end{matrix}} \qquad ( 2 )$$

wherein E_{S} is the signal source matching error, S_{11AS} the actual value of the short-circuit parameter, S_{11AO} the actual value of the open-circuit parameter, S_{11AL} the actual value of the load parameter, S_{11MS} the measured value of the short-circuit parameter, S_{11MO} the measured value of the open-circuit parameter, and S_{11ML} the measured value of the load parameter.

The reflection path error equation is expressed by Equation (3):

$${E}_{R T} = \frac{{S}_{11 M} - {E}_{D} - {S}_{11 M} * {E}_{S} * {S}_{11 A} + {E}_{D} * {E}_{S} * {S}_{11 A}}{{S}_{11 A}} \qquad ( 3 )$$

wherein E_{RT} is the reflection path error, E_{D} the directivity error, E_{S} the signal source matching error, S_{11MO} the measured value of the open-circuit parameter, and S_{11AO} the actual value of the open-circuit parameter.

After the directivity error, the signal source matching error and the reflection path error are obtained, the process proceeds to Step S14. In Step S14, substitute the directivity error, the signal source matching error and the reflection path error into an RF parameter equation to work out the actual value of the RF parameter. The RF parameter equation is expressed by Equation (4):

(S_{11M}−E_{D})*(1−E_{S}−S_{11A})=E_{RT}−S_{11A} (4)

wherein E_{RT} is the reflection path error, E_{D} the directivity error, E_{S} the signal source matching error, S_{11M} the measured value of the RF parameter, and S_{11A} the actual value of the RF parameter. Thereby, the actual value of the RF parameter is worked out. Then, the process proceeds to Step S16.

In Step S16, examine whether the actual value of the RF parameter is smaller than a preset dB value (−50 dB). If yes, the actual value of the RF parameter is smaller than the preset dB value, the process proceeds to Step S18 to use the actual value of the RF parameter, which is obtained in Step S14, to calibrate the RF parameter. If no, the actual value of the RF parameter is not smaller than a preset dB value, the process returns to Step S10 to undertake measurements and calculate the actual value of the RF parameter once again.

All the abovementioned directivity error equation, signal source matching error equation, reflection path error equation, and RF parameter equation are derived from Equation (5):

$${S}_{11 M} = {E}_{D} + \frac{{S}_{11 A} \cdot {E}_{R T}}{1 - {E}_{S} {S}_{11 A}} \qquad ( 5 )$$

The process of deriving the directivity error equation, signal source matching error equation, reflection path error equation, and RF parameter equation from Equation (5) is described below.

Rearrange Equation (5) to obtain Equation (6):

(S_{11M}−E_{D})*(1−E_{S}−S_{11A})=E_{RT}−S_{11A} (6)

Rearrange Equation (6) to obtain Equation (7):

S_{11M}−E_{D}−S_{11M}*E_{S}*S_{11A}+E_{D}*E_{S}*S_{11A}−E_{RT}*S_{11A}=0 (7)

Rearrange Equation (7) to obtain the reflection path error equation (3):

$${E}_{R T} = \frac{{S}_{11 M} - {E}_{D} - {S}_{11 M} * {E}_{S} * {S}_{11 A} + {E}_{D} * {E}_{S} * {S}_{11 A}}{{S}_{11 A}} \qquad ( 3 )$$

Substitute S_{11MO} the measured value of the open-circuit parameter and S_{11AO} the actual value of the open-circuit parameter into Equation (7) to obtain Equation (8):

S_{11MO}−E_{D}−S_{11MO}*E_{S}*S_{11AO}+E_{D}*E_{S}*S_{11AO}−E_{RT}*S_{11AO}=0 (8)

Substitute S_{11MS} the measured value of the short-circuit parameter and S_{11AS} the actual value of the short-circuit parameter into Equation (7) to obtain Equation (9):

S_{11MS}−E_{D}−S_{11MS}*E_{S}*S_{11AS}+E_{D}*E_{S}*S_{11AS}−E_{RT}*S_{11AS}=0 (9)

Substitute S_{11ML} the measured value of the load parameter and S_{11AL} the actual value of the load parameter into Equation (7) to obtain Equation (10):

S_{11ML}−E_{D}−S_{11ML}*E_{S}*S_{11AL}+E_{D}*E_{S}*S_{11AL}−E_{RT}*S_{11AL}=0 (10)

Substitute Equations (8) and (9) into the formula [Equation (8)*the actual value of the short-circuit parameter (S_{11AS})]−[Equation (9)*the actual value of the open-circuit parameter (S_{11AO})] to obtain Equation (11):

(S_{11MO}*S_{11AO}*S_{11AS}−S_{11MS}*S_{11AS}*S_{11AO})*E_{S}+(S_{11S}−S_{11AO})*E_{D}+(S_{11AO}*S_{11AS}−S_{11AS}*S_{11AO})*E_{RT}=S_{11MO}*S_{11AS}−S_{11MS}*S_{11AO} (11)

Substitute Equations (8) and (10) into the formula [Equation (8)*the actual value of the open-circuit parameter (S_{11AO})]−[Equation (10)*the actual value of the open-circuit parameter (S_{11AO})] to obtain Equation (11):

(S_{11MO}*S_{11AO}*S_{11AL}−S_{11ML}*S_{11AL}*S_{11AO})*E_{S}+(S_{11AL}−S_{11AO})*E_{D}+(S_{11AO}*S_{11AL}−S_{11AL}*S_{11AO})*E_{RT}=S_{11MO}*S_{11AL}−S_{11ML}*S_{1AO} (12)

Solve Equation (11) and Equation (12) simultaneously to obtain the directivity error equation (1):

$${E}_{D} = \frac{\begin{matrix}{S}_{11 A L} * {S}_{11 M L} * {S}_{11 A O} * {S}_{11 M S} - \\ {S}_{11 A L} * {S}_{11 M L} * {S}_{11 M O} * {S}_{11 A S} - \\ {S}_{11 A L} * {S}_{11 A O} * {S}_{11 M O} * {S}_{11 M S} + \\ {S}_{11 M L} * {S}_{11 A O} * {S}_{11 M O} * {S}_{11 A S} + \\ {S}_{11 A L} * {S}_{11 M O} * {S}_{11 A S} * {S}_{11 M S} - \\ {S}_{11 M L} * {S}_{11 A O} * {S}_{11 A S} * {S}_{11 M S}\end{matrix}}{\begin{matrix}{S}_{11 A L} * {S}_{11 M L} * {S}_{11 A O} - \\ {S}_{11 A L} * {S}_{11 A O} * {S}_{11 M O} - \\ {S}_{11 A L} * {S}_{11 M L} * {S}_{11 A S} + \\ {S}_{11 A O} * {S}_{11 M O} * {S}_{11 A S} + \\ {S}_{11 A L} * {S}_{11 A S} * {S}_{11 M S} - \\ {S}_{11 A O} * {S}_{11 A S} * {S}_{11 M S}\end{matrix}} \qquad ( 1 )$$

and the signal source matching error equation (2):

$${E}_{S} = \frac{\begin{matrix}{S}_{11 A L} * {S}_{11 M O} - {S}_{11 M L} * {S}_{11 A O} - \\ {S}_{11 A L} * {S}_{11 M S} + {S}_{11 M L} * {S}_{11 A S} + \\ {S}_{11 A O} * {S}_{11 M S} - {S}_{11 M O} * {S}_{11 A S}\end{matrix}}{\begin{matrix}{S}_{11 A L} * {S}_{11 M L} * {S}_{11 A O} - \\ {S}_{11 A L} * {S}_{11 A O} * {S}_{11 M O} - \\ {S}_{11 A L} * {S}_{11 M L} * {S}_{11 A S} + \\ {S}_{11 A O} * {S}_{11 M O} * {S}_{11 A S} + \\ {S}_{11 A L} * {S}_{11 A S} * {S}_{11 M S} - \\ {S}_{11 A O} * {S}_{11 A S} * {S}_{11 M S}\end{matrix}} \qquad ( 2 )$$

Via the abovementioned deductions, the directivity error equation (1), the signal source matching error equation (2), the reflection path error equation (3) and the RF parameter equation (4) are obtained and used to automatically calculate the RF parameter.

In the present invention, the calibration equations thereof cooperate with the non-standard measured values to replace the expensive standard calibration kit and achieve more accurate calibration. Besides, the computation of the calibration equations used by the RF parameter calibration method of the present invention uses is simpler. Therefore, the RF parameter calibration method of the present invention has a lower cost than the conventional calibration method using the standard calibration kit.

The present invention has been demonstrated with the embodiments described above. However, it should be understood: these embodiments are only to exemplify the present invention but not to limit the scope of the present invention. Any equivalent modification or variation according to the spirit of the present invention is to be also included within the scope of the present invention.

What is claimed is:

1. A radio-frequency parameter calibration method comprising
Step (a): measuring an open-circuit parameter, a short-circuit parameter and a load parameter of a radio-frequency (RF) parameter circuit of a tested object;
Step (b): respectively substituting a measured value of said open-circuit parameter, a measured value of said short-circuit parameter and a measured value of said load parameter into a directivity error equation, a signal source matching error equation, and a reflection path error equation to obtain a directivity error, a signal source matching error, and a reflection path error;
Step (c): substituting said directivity error, said signal source matching error and said reflection path error into an RF parameter equation to work out an actual value of an RF parameter, wherein said RF parameter equation is expressed by
(S_{11M}−E_{D})*(1−E_{S}−S_{11A})=E_{RT}−S_{11A}
wherein E_{RT} is said reflection path error, E_{D} said directivity error, E_{S} said signal source matching error, S_{11M} a measured value of said RF parameter, and S_{11A} said actual value of said RF parameter; and
Step (d): examining whether said actual value of said RF parameter is smaller than a preset dB value; if yes, undertaking calibration; if no, returning to Step (a) to undertake measurements once again.

2. The radio-frequency parameter calibration method according to claim 1, wherein said directivity error equation is expressed by
$${E}_{D} = \frac{\begin{matrix}{S}_{11 A L} * {S}_{11 M L} * {S}_{11 A O} * {S}_{11 M S} - \\ {S}_{11 A L} * {S}_{11 M L} * {S}_{11 M O} * {S}_{11 A S} - \\ {S}_{11 A L} * {S}_{11 A O} * {S}_{11 M O} * {S}_{11 M S} + \\ {S}_{11 M L} * {S}_{11 A O} * {S}_{11 M O} * {S}_{11 A S} + \\ {S}_{11 A L} * {S}_{11 M O} * {S}_{11 A S} * {S}_{11 M S} - \\ {S}_{11 M L} * {S}_{11 A O} * {S}_{11 A S} * {S}_{11 M S}\end{matrix}}{\begin{matrix}{S}_{11 A L} * {S}_{11 M L} * {S}_{11 A O} - \\ {S}_{11 A L} * {S}_{11 A O} * {S}_{11 M O} - \\ {S}_{11 A L} * {S}_{11 M L} * {S}_{11 A S} + \\ {S}_{11 A O} * {S}_{11 M O} * {S}_{11 A S} + \\ {S}_{11 A L} * {S}_{11 A S} * {S}_{11 M S} - \\ {S}_{11 A O} * {S}_{11 A S} * {S}_{11 M S}\end{matrix}}$$
wherein E_{D} is said directivity error, S_{11AS} an actual value of said short-circuit parameter, S_{11AO} an actual value of said open-circuit parameter, S_{11AL} an actual value of said load parameter, S_{11MS} said measured value of the short-circuit parameter, S_{11MO} said measured value of said open-circuit parameter, and S_{11ML} said measured value of said load parameter.

3. The radio-frequency parameter calibration method according to claim 1, wherein said signal source matching error equation is expressed by
$${E}_{S} = \frac{\begin{matrix}{S}_{11 A L} * {S}_{11 M O} - {S}_{11 M L} * {S}_{11 A O} - \\ {S}_{11 A L} * {S}_{11 M S} + {S}_{11 M L} * {S}_{11 A S} + \\ {S}_{11 A O} * {S}_{11 M S} - {S}_{11 M O} * {S}_{11 A S}\end{matrix}}{\begin{matrix}{S}_{11 A L} * {S}_{11 M L} * {S}_{11 A O} - \\ {S}_{11 A L} * {S}_{11 A O} * {S}_{11 M O} - \\ {S}_{11 A L} * {S}_{11 M L} * {S}_{11 A S} + \\ {S}_{11 A O} * {S}_{11 M O} * {S}_{11 A S} + \\ {S}_{11 A L} * {S}_{11 A S} * {S}_{11 M S} - \\ {S}_{11 A O} * {S}_{11 A S} * {S}_{11 M S}\end{matrix}}$$
wherein E_{S} is said signal source matching error, S_{11AS} an actual value of said short-circuit parameter, S_{11AO} an actual value of said open-circuit parameter, S_{11AL} an actual value of said load parameter, S_{11MS} said measured value of said short-circuit parameter, S_{11MO} said measured value of said open-circuit parameter, and S_{11ML} said measured value of said load parameter.

4. The radio-frequency parameter calibration method according to claim 1, wherein said reflection path error equation is expressed by
$${E}_{R T} = \frac{{S}_{11 M} - {E}_{D} - {S}_{11 M} * {E}_{S} * {S}_{11 A} + {E}_{D} * {E}_{S} * {S}_{11 A}}{{S}_{11 A}}$$
wherein E_{RT} is said reflection path error, E_{D} said directivity error, E_{S} said signal source matching error, S_{11MO} said measured value of said open-circuit parameter, and S_{11AO} an actual value of said open-circuit parameter.

5. The radio-frequency parameter calibration method according to claim 1, wherein said preset dB value is −50 dB.
